(19) United States
(12) Patent Application Publication
(10) Pub. No.: US 2015/0343569 A1
(43) Pub. Date: Dec. 3, 2015

(54) SN-AG-CU-BASED SOLDER POWDER AND SOLDER PASTE USING SAID POWDER

(71) Applicant: MITSUBISHI MATERIALS CORPORATION, Chiyoda-ku, Tokyo (JP)

(72) Inventors: Koutarou Iwata, Iwaki-shi (JP); Hiroki Muraoka, Iwaki-shi (JP); Kanji Kuba, Iwaki-shi (JP)

(21) Appl. No.: 14/759,499

(22) PCT Filed: Jan. 21, 2014
(86) PCT No.: PCT/JP2014/051037

§ 371 Date: Jul. 7, 2015

(30) Foreign Application Priority Data
Jan. 28, 2013 (JP) 2013-012970

(51) Int. Cl. B23K 35/26; H05K 3/34; C22C 13/00; B23K 35/02; B23K 35/36

(52) U.S. Cl. CPC B23K 35/262; B23K 35/0244; B23K 35/025; B23K 35/3618; C22C 13/00; H05K 3/3463

(57) ABSTRACT

The present invention is directed to an Sn—Ag—Cu-based solder powder which comprises solder powder having an average particle size of 5 μm or less, and a dried material of a solution of hydroxybenzoic acid or an ester thereof having a melting point of 250° C. or lower being attached onto a surface of the solder powder as an additive, wherein the additive is preferably salicylic acid, ethyl 3,4-dihydroxybenzoate or ethyl 3,5-dihydroxybenzoate, an attached amount of the additive is preferably 0.01 to 1.0 part by mass based on 100 parts by mass of the total amount of the components of tin, silver and copper contained in the solder powder, a content of the silver is 0.1 to 10% by mass when the total amount of the components of tin, silver and copper is made 100% by mass, a content of the copper is 0.1 to 2.0% by mass when the total amount of the components of tin, silver and copper is made 100% by mass, and a remainder being tin.

### TECHNICAL FIELD

The present invention relates to lead-free solder powder for fine pitch and a solder paste using the powder. More specifically, it relates to fine Sn—Ag—Cu-based solder powder having an average particle size of 5 μm or less and a solder paste using the powder. This International Application claims the priority based on Japanese Patent Application No. 012970 filed on Jan. 28, 2013 (Patent Application No. 2013-012970), and the whole contents of the Patent Application No. 2013-012970 are incorporated herein by reference.

### BACKGROUND ART

A solder to be used for bonding of electronic parts is advanced to be lead-free from the viewpoint of environment, and now a solder powder containing tin is employed as a main component. As a method for obtaining a fine metal powder such as the solder powder, there have been known, in addition to the atomizing method such as the gas atomizing method and the rotary disc method, etc., the melt spinning method, the rotary electrode method, the mechanical process and the chemical process, etc. The gas atomizing method is a method in which a metal is melted by an induction furnace or a gas furnace, the molten metal is flowed down from a nozzle at the bottom of a tundish, and a high pressure gas is blown thereto from the circumference to powderize the metal. The rotary disc method is also called as the centrifugal force atomizing method, and is a method to prepare fine powder by dropping a molten metal on a disc rotating at high speed to apply a shearing force to the tangential direction to fracture the metal.

On the other hand, finer pitch of bonding parts is also progressing with miniaturization of electronic parts, and solder powder having a finer particle size is desired, so that improvement in technologies for such a finer pitch has also been actively carried out. For example, as a technique in which the gas atomizing method has been improved, it has been disclosed a method for manufacturing metal fine powder in which a molten metal in a gas-entrained state is jetted from a nozzle and a high pressure gas is blown from the circumference of the nozzle against the metal (for example, see Patent Document 1.). According to the method described in Patent Document 1, by entraining the gas into the molten metal when it passes through the nozzle, the molten metal has already been separated at the time of tapping from the nozzle whereby finer powder can be produced.

In addition, as a technique in which the rotary disc method has been improved, it has been disclosed a preparation method of metal fine powder in which a mesh is arranged to a rotary member as a means for adjusting a size of the metal fine powder, and a molten metal is scattered through the mesh (for example, see Patent Document 2.). According to the method describeds in Patent Document 2, finer metal powder can be formed with good efficiency as compared with the conventional rotary disc method.

Further, it has been disclosed a solder powder which is obtained by the wet reduction method, that a yield of the solder powder having an average particle size of 5 μm or less is extremely high (for example, see Patent Document 3.). This solder powder comprises a ternary solder powder comprising a metal particle which comprises a center core, a covering layer encapsulating the center core, and an outermost layer encapsulating the covering layer to improve wettability of a paste for solder or strength required for a solder bump. This solder powder comprises a metal particle in which all the three kinds of metals are contained in one particle, so that the composition is more uniform as compared with a solder powder in which different kinds of single-metal powders are simply mixed. Also, it has a structure in which a center core, a covering layer and an outermost layer are successively coated in this order depending on an ionization tendency of metal elements forming the respective layers, so that a process of reducing a metal ion to precipitate a powder is not so complicated whereby it is also excellent in mass productivity.

### PRIOR ART REFERENCES

### Patent Documents

JP 2004-018956A (claim 1, paragraph [0014])
JP H06-264116A (claim 1, paragraph [0013], FIG. 3)
JP2008-149366A (claim 1, paragraph [0014] to paragraph [0016])

### SUMMARY OF THE INVENTION

### Problems to be Solved by the Invention

For obtaining finer powders according to the so-called atomizing method disclosed in the above-mentioned conventional Patent Documents 1 and 2, however, it is necessary to further classify the metal powder obtained by the method to collect finer powder having 5 μm or less which can correspond to fine pitch. Therefore, the yield thereof becomes very bad. On the other hand, the powder having 7 μm or so can be obtained by the above method with a good yield, but the powder with such a particle size cannot sufficiently comply with the fine pitch in recent years.

In addition, in the solder powder disclosed in the above-mentioned Patent Document 3, the particle size is extremely small as 5 μm or less and the outermost layer is constituted by tin which is easily oxidized so that oxidation of the surface of the powder is likely caused. When the powder is oxidized, there occur the problems that a melting procedure at the time of forming a solder bump takes time, and wettability is poor.

An object of the present invention is to provide an Sn—Ag—Cu-based solder powder which is a fine solder powder suitable for a paste for solder realizing fine pitch, which is excellent in meltability and wettability at the time of reflow, and a solder paste using the powder.

Another object of the present invention is to provide a solder powder having the same activating effect as an activating agent in a flux for a paste when it is made to be a paste.

### Means for Solving the Problems

The first aspect of the present invention is directed to an Sn—Ag—Cu-based solder powder which comprises a solder powder having an average particle size of 5 μm or less, and a dried material of a solution of hydroxybenzoic acid or an ester thereof having a melting point of 250° C. or lower being attached onto a surface of the solder powder as an additive. Incidentally, the term “attach” in the present specification means not the state obtained by simply mixing additive powder and solder powder, but the state obtained by adding an additive solution in which powder of the additive has been mixed with water, etc., and stirred, to the solder powder which is a compound of the metal components, mixing the mixture under stirring and drying the same without separating into a solid and a liquid.

The second aspect of the present invention is an invention based on the first aspect, wherein the above-mentioned additive is salicylic acid, ethyl 3,4-dihydroxybenzoate or ethyl 3,5-dihydroxybenzoate.

The third aspect of the present invention is an invention based on the first aspect, wherein an attached amount of the above-mentioned additive is 0.01 to 1.0 part by mass based on 100 parts by mass of the total amount of the components of tin, silver and copper contained in the solder powder, a content of the silver is 0.1 to 10% by mass when the total amount of the components of tin, silver and copper is made 100% by mass, a content of the copper is 0.1 to 2.0% by mass when the total amount of the components of tin, silver and copper is made 100% by mass, and the remainder is tin.

The fourth aspect of the present invention is an invention based on the first aspect, wherein at least one of bismuth, germanium, nickel and indium is contained in an amount of 1.0% by mass or less when the total amount of the solder powder is made 100% by mass.

The fifth aspect of the present invention is a paste for a solder obtained by mixing the Sn—Ag—Cu-based solder powder of the first aspect and a flux for solder to make a paste.

The sixth aspect of the present invention is a paste for solder of the fifth aspect which is used for mounting an electronic part.

### Effects of the Invention

The Sn—Ag—Cu-based solder powder of the first aspect of the present invention comprises hydroxybenzoic acid or an ester thereof having a melting point of 250° C. or lower being attached onto the surface of the solder powder as an additive, so that in spite of the particle size being extremely fine as 5 μm or less, the surface of the solder powder is difficultly oxidized. Therefore, it is excellent in meltability and wettability at the time of reflow. Also, when a paste is to be prepared, an antioxidizing effect effectively acts as compared to the solder paste obtained by adding an antioxidant separately, so that even when the antioxidant to be added is a little amount, a paste excellent in wettability or melting and diffusion properties during reflow can be prepared. Further, when the solder powder is used, the above-mentioned additive exerts the same activating effect (more specifically, an effect of removing an oxide film at the surface of the solder powder) as those of an activating agent, so that a paste excellent in wettability or melting and diffusion properties during reflow can be prepared. Moreover, the solder powder is fine powder as an average particle size of 5 μm or lower, so that when a paste for a solder using the solder powder as a starting material is printed onto a substrate, etc., it can be printed with a fine pitch pattern. Furthermore, the additive has a melting point of 250° C. or lower, so that the additive is thermally decomposed and evaporated before melting the solder powder, whereby it is preferred since there is no harmful effect of the additive in the soldering process.

By employing salicylic acid, ethyl 3,4-dihydroxybenzoate or ethyl 3,5-dihydroxybenzoate as the above-mentioned additive of the Sn—Ag—Cu-based solder powder of the second aspect of the present invention, a paste excellent in wettability or melting and diffusion properties during reflow can be prepared.

In the Sn—Ag—Cu-based solder powder of the third aspect of the present invention, the attached amount of the above-mentioned additive is 0.01 to 1.0 part by mass based on 100 parts by mass of the total amount of the components of tin, silver and copper contained in the solder powder, the content of the silver is 0.1 to 10% by mass when the total amount of the components of tin, silver and copper is made 100% by mass, the content of the copper is 0.1 to 2.0% by mass when the total amount of the components of tin, silver and copper is made 100% by mass, and the remainder being tin. Thus, in the solder powder of the present invention, the above-mentioned additive is attached to the surface of the solder powder with a predetermined attached amount, so that an antioxidant effect of the solder powder is extremely high. In addition, the reason why the contents of the tin, silver and copper are each within the above-mentioned range is to make the melting point of the solder powder low by preventing from fluctuating the composition from a eutectic point, and to improve mechanical strength by suppressing increase in electric resistance of the solder alloy at the formed solder bump.

The solder powder of the fourth aspect of the present invention may further contain at least one of bismuth, germanium, nickel and indium in a ratio of 1.0% by mass or less when the total amount of the solder powder is made 100% by mass, other than the above-mentioned tin, silver and copper. By the addition of the above-mentioned element(s), effects of lowering a melting point and improving the strength of the solder powder, etc., can be obtained.

The paste for a solder of the fifth aspect of the present invention can be obtained by using the above-mentioned solder powder of the present invention. Therefore, the paste for solder is rapidly melted at the time of reflow, and the wettability is extremely good, so that occurrence of the so-called solder balls in which a melted paste is scattered with a spherical shape at the time of forming a solder bump can be markedly suppressed.

The paste for a solder of the sixth aspect of the present invention is rapidly melted at the time of reflow, the wettability is extremely good, and it can be printed to a substrate, etc., with a fine pitch pattern, so that it can be suitably used for mounting of electronic parts.

### EMBODIMENTS TO CARRY OUT THE INVENTION

Next, embodiments to carry out the present invention are explained. The Sn—Ag—Cu-based solder powder of the present invention is a solder powder having an average particle size of 5 μm or less, preferably 1 to 5 μm. The solder powder may be constituted by a center core, a coating layer coating the center core and an outermost layer coating the coating layer. The reason why the average particle size of the solder powder has been limited to 5 μm or less is that if it exceeds 5 μm, a paste for solder cannot be printed to a substrate, etc., with a fine pitch pattern, and finer electronic parts cannot be mounted by the paste for solder. Incidentally, in the present specification, the average particle size of the solder powder means a volume accumulation median diameter (Median diameter, D₅₀) measured by a particle size distribution measurement device (manufactured by HORIBA Ltd., laser diffraction/scattering type particle size distribution measurement device LA-950) using a laser diffraction scattering method. In addition, it is fine powder having an average particle size of 5 μm or less, so that it can be printed with a fine pitch pattern when a paste for solder using the powder as a starting material is printed to a substrate, etc.

When the solder powder is constituted by a center core, a coating layer coating the center core and an outermost layer coating the coating layer, it contains not only the state in which the coating layer is completely coating the center core, but also the structure in which the coating layer is so intervened that it coats a part of the center core. It is preferred that the content of the silver in the solder powder is 0.1 to 10% by mass when the total amount of the components of tin, silver and copper is made 100% by mass, and the content of the copper is 0.1 to 2.0% by mass when the total amount of the components of tin, silver and copper is made 100% by mass, and the remainder being tin. Here, the reasons why the contents of the above-mentioned metals are limited to the above-mentioned ranges are to make the melting point of the solder powder low by preventing from fluctuating the composition from a eutectic point, and to improve mechanical strength by suppressing increase in electric resistance of the solder alloy at the formed solder bump.

Also, if the ratio of the silver or the copper is extremely little or extremely much, wettability at the time of reflow of the paste tends to be worsened. This is considered by the reason that if the ratio of the silver or the copper is extremely little, the powder becomes near to the composition of the tin single material which is easily oxidized, and on the other hand, if the ratio of the silver or the copper is extremely much, the solid-liquid co-presenting region is broad and the fluidity of the melt is low. Further, the ratio of the silver or the copper is extremely much, the ratio of the tin becomes little and it does not show a low melting point required as a solder powder. Moreover, the ratio of the silver or the copper is extremely little, the ratio of the tin becomes much, so that wettability is lowered and the mechanical strength of the formed solder bump is lowered. Among these, it is particularly preferred that the content of the silver is 1.0 to 5.0% by mass when the total amount of the components of tin, silver and copper is made 100% by mass, the content of the copper is 0.3 to 0.7% by mass when the total amount of the components of tin, silver and copper is made 100% by mass, and the remainder being tin.

The Sn—Ag—Cu-based solder powder of the present invention comprises hydroxybenzoic acid or an ester thereof having a melting point of 250° C. or lower being attached onto the surface of the solder powder as an additive. Thus, in the solder powder of the present invention, since these additives are attached onto the surface of the solder powder, oxidation of the surface of the solder powder difficultly occurs even when the outermost layer is constituted by tin. Therefore, it is excellent in meltability and wettability at the time of reflow.

Also, the Sn—Ag—Cu-based solder powder of the present invention has the structure in which these additives are attached onto the surface of the solder powder. When a paste is to be prepared, it can be considered the method in which the additive is separately added into the paste, but when the solder powder takes the structure in which the additive is attached onto the surface of the solder powder, contacting of the solder powder with the additive is increased, so that an antioxidizing effect can be obtained even when the amount thereof is a little. Therefore, when the solder powder of the present invention is used, a solder paste excellent in wettability and melt diffusibility can be prepared as compared with the paste obtained by adding the additive separately.

The attached amount of the additive is preferably 0.01 to 1.0 part by mass based on 100 parts by mass of the total amount of the components of tin, silver and copper contained in the solder powder. If the attached amount of the additive is less than the lower limit value, the antioxidizing effect cannot sufficiently be obtained, while if it exceeds the upper limit value, meltability is lowered in some cases. Among these, the attached amount of the additive is particularly preferably 0.05 to 0.5 part by mass based on 100 parts by mass of the total amount of the components of tin, silver and copper contained in the solder powder.

Also, at least one of bismuth, germanium, nickel and indium may be further contained in the solder powder with a ratio of 1.0% by mass or less when the total amount of the solder powder is made 100% by mass other than the metals of the above-mentioned tin, silver and copper. By the addition of the above-mentioned element(s), effects of lowering a melting point and improving the strength of the solder powder, etc., can be obtained.

Subsequently, a method for manufacturing the above-mentioned Sn—Ag—Cu-based solder powder of the present invention is explained. First, a compound containing silver, a compound containing copper, a compound containing tin and a dispersing agent are each added to a solvent and mixed to prepare a dissolved solution. Contents of the compound containing silver, the compound containing copper and the compound containing tin in the dissolved solution are so adjusted that the contents of the respective metal elements will become within the above-mentioned ranges after manufacture of the solder powder. When bismuth, germanium, nickel or indium is to be contained, a compound(s) containing these metals is/are added to the dissolved solution.

Also, as the above-mentioned dissolved solution, silver powder is used in place of the above-mentioned compound containing silver, and the silver powder and a dispersing agent are added to a solvent and mixed to prepare a dispersion of the silver powder, then, the above-mentioned compound containing copper and a compound containing tin are directly added to the dispersion and mixed to dissolve therein, or a compound containing copper and a compound containing tin are each dissolved in a solvent to previously prepare two kinds of metal solutions, and these solutions are added to the dispersion of the above-mentioned silver powder and mixed, and the resulting dissolved solution in which the silver powder has been dispersed may be used. A ratio of the silver powder, the compound containing copper and the compound containing tin to be used at this time is so adjusted that the contents of the respective metal elements become within the above-mentioned ranges after manufacture of the solder powder.

The silver compound to be used for preparing the dissolved solution may be mentioned silver (I) sulfate, silver (I) chloride or silver (I) nitrate, etc. On the other hand, the silver powder to be used in place of the silver compound may be silver powder having an average particle size of 0.1 to 2.0 μm, which is obtained not only by the chemical means by the reducing reaction, but also silver powder obtained by the physical means such as the atomizing method. Also, the copper compound to be used for preparing the dissolved solution may be mentioned copper (II) chloride, copper (II) sulfate or copper acetate, etc., and the tin compound may be mentioned tin (II) chloride, tin (II) sulfate, tin (II) acetate, tin (II) oxalate, etc. Among these, when the dissolved solution in which the compound containing silver, the compound containing copper and the compound containing tin have been dissolved is to be used, it is particularly preferred to use, as the silver compound, the copper compound and the tin compound, each sulfate of silver (II) sulfate, copper (II) sulfate and tin (II) sulfate. This is because, when the silver compound is to be used, if chlorides of copper and tin are used, coarse particles of the silver chloride are generated, and the solder powder obtained by using the same as a center core becomes particles having a larger average particle size than those of the intended particles in some cases.

On the other hand, when the dissolved solution in which the silver powder has been dispersed is used, it is particularly preferred to use, as the copper compound and the tin compound, each sulfate of copper (II) sulfate and tin (II) sulfate, or each hydrochloride of copper (II) chloride and tin (II) chloride. The reason why not only the sulfate but also the hydrochloride have been suitably used for preparing the dissolved solution in the method of using the dissolved solution in which the silver powder has been dispersed is that only the surface of the silver powder becomes a chloride, the average particle size of the silver powder has not been substantially changed, and the solder powder obtained by using the above particles as a center core likely becomes the intended average particle size.

The solvent may be mentioned water, an alcohol, an ether, a ketone, an ester, etc. Also, the dispersing agent may be mentioned a cellulose series, a vinyl series, a polyvalent alcohol, etc., and in addition, gelatin, casein, etc., can be used. A pH of the prepared dissolved solution is then adjusted. The pH is preferably adjusted to the range of 0 to 2.0 considering redissolution of the generated solder powder, etc. Incidentally, after adding the above-mentioned metal compounds to the solvent, respectively, and dissolving therein, a complexing agent is then added thereto to make each metal element complex, and the dispersing agent may be added to the mixture. By adding the complexing agent, metal ions are not precipitated at a pH in the range of an alkaline side, and the synthesis can be carried out with a wide range. The complexing agent may be mentioned succinic acid, tartaric acid, glycolic acid, lactic acid, phthalic acid, malic acid, citric acid, oxalic acid, ethylenediaminetetraacetic acid, iminodiacetic acid, nitrilotriacetic acid or a salt thereof, etc.

Next, an aqueous solution into which a reducing agent has been dissolved is prepared, and a pH of the aqueous solution is adjusted to substantially the same degree as that of the dissolved solution prepared as mentioned above. The reducing agent may be mentioned a boron hydride such as sodium tetrahydroborate, dimethylamine borane, etc., a nitrogen compound such as a hydrazine, etc., and a metal ion such as a trivalent titanium ion and a divalent chromium ion, etc.

Next, an aqueous reducing agent solution is added to the above-mentioned dissolved solution and the mixture is mixed, each metal ion in the dissolved solution is reduced to obtain a dispersion in which metal powder is dispersed in the liquid. In the reducing reaction, when the above-mentioned dissolved solution in which the compound containing silver, the compound containing copper and the compound containing tin have been dissolved therein is used, silver which is nobler than tin and copper is firstly reduced, then, copper which is noble than tin is reduced, and finally tin is reduced. On the other hand, when the dissolved solution in which the silver powder has been dispersed is used, copper which is nobler than tin is firstly reduced to precipitate copper on the surface of the silver particles, and then, tin is reduced. According to this procedure, a metal powder having an average particle size of 5 μm or less, which is constituted by a center core comprising silver, a covering layer comprising copper which covers the center core, and an outermost layer comprising tin which covers the coating layer, is formed. The method for mixing the dissolved solution and the aqueous reducing agent solution may be mentioned a method in which the aqueous reducing agent solution is added dropwise to the dissolved solution in an vessel with a predetermined addition rate, and stirring the mixture by a stirrer, etc., or a method in which by using a reaction tube having a predetermined diameter, the both solutions are injected into the reaction tube with predetermined flow rates to mix these solutions, etc.

Then, the dispersion is separated into a solid and a liquid by decantation, etc., and the recovered solid component is washed with water, or an aqueous hydrochloric acid solution, an aqueous nitric acid solution, an aqueous sulfuric acid solution each pH of which has been adjusted to 0.5 to 2, or methanol, ethanol, acetone, etc. After washing, the solid and the liquid are separated again and the solid component is recovered. The procedures from washing to solid-liquid separation are repeated preferably 2 to 5 times.

Next, an additive solution in which an additive such as hydroxybenzoic acid and an ester thereof having a melting point of 250° C. or lower has been dissolved in a solvent, preferably water, ethanol or acetone, etc., is prepared. At this time, an amount of the additive to be used is so adjusted that the attached amount of the additive to be attached onto the surface of the solder powder will become within the above-mentioned range. Also, a concentration of the additive solution is preferably adjusted to a concentration of about 1 to 20% by mass for the reasons of solubility and drying efficiency of the additive.

And the additive solution is added to the solid component which has been separated to a solid and liquid and washed but before drying, and stirred under the conditions of preferably at a rotation speed of 100 to 500 rpm for 5 to 60 minutes. At this time, when the above-mentioned rotation speed and time are less than the lower limit values, there is a case to cause an inconvenience where it is not sufficiently dispersed and stirred, while if it exceeded the upper value, the degrees of dispersion and stirring are not changed.

This is vacuum dried without separating the solid and the liquid, whereby the solder powder of the present invention can be obtained.

According to the above procedures, the Sn—Ag—Cu-based solder powder of the present invention can be obtained. The solder powder can be suitably used as a material for a paste for solder which can be obtained by mixing with a flux for solder to make a paste. Preparation of the paste for solder can be carried out, for example, by mixing a flux for solder in an amount preferably 10 to 30% by mass, further preferably 10 to 25% by mass and make a paste. The reason why the mixed amount of the flux for solder be made to be 10 to 30% by mass is that, if it is less than 10% by mass, a paste cannot be prepared due to lack of the flux, while if it exceeds 30% by mass, the content of the flux in the paste is too much and the content of the metal becomes less and a solder bump with a desired size cannot be obtained at the time of melting the solder.

The paste for solder uses the above-mentioned solder powder of the present invention as a material, so that meltability and wettability thereof are extremely good, and it is excellent in difficultly generating a solder ball(s). Also, the paste for solder is prepared by fine solder powder of 5 μm or less, when the paste for solder is used, printing can be carried out to the substrate, etc., with a fine pitch pattern, and a solder bump with less unevenness in height can be formed. Therefore, the paste for solder can be suitably used for mounting finer electronic parts.

### EXAMPLES

Next, Examples of the present invention are explained in detail with Comparative examples.

### Example 1

First, to 50 mL of water were added 1.59×10⁻⁴ mole of copper (II) sulfate, 4.10×10⁻⁴ mole of silver (I) sulfate and 2.62×10⁻² mole of tin (II) sulfide, and the mixture was stirred by using a stirrer at a rotation speed of 300 rpm for 5 minutes to prepare a dissolved solution. The dissolved solution was adjusted to a pH of 0.5 with sulfuric acid, then, 0.5 g of polyvinyl alcohol 500 (polyvinyl alcohol having an average molecular weight of 500) was added thereto as a dispersing agent, and the mixture was further stirred at a rotation speed of 300 rpm for 10 minutes.

Then, to the dissolved solution was added 50 mL of 1.58 mole/L of a divalent aqueous chromium ion solution a pH of which has been adjusted to 0.5 with an addition speed of 50 mL/sec, and the resulting mixture was stirred at a rotation speed of 500 rpm for 10 minutes to reduce the respective metal ions whereby a dispersion in which metal powder had been dispersed in the liquid was obtained. This dispersion was allowed to stand for 60 minutes to precipitate the generated metal powder, the supernatant was discarded, 100 mL of water was added to the precipitate and the mixture was stirred at a rotation speed of 300 rpm for 10 minutes, and this operation was repeated three times to carry out washing.

Next, to 20 mL of water was added 20 mg of salicylic acid (2-hydroxybenzoic acid) as an additive to prepare an additive solution. The additive solution was added to 4.0 g of the above-mentioned metal powder which had been washed and before drying, and the resulting mixture was stirred under the conditions at a rotation speed of 300 rpm for 30 minutes.

Thereafter, the resulting material was dried by a vacuum dryer to obtain Sn—Ag—Cu-based solder powder in which 0.49 part by mass of salicylic acid had been attached to the surface of the solder powder based on 100 parts by mass of the total amount of components of tin, silver and copper contained in the solder powder. The obtained solder powder was subjected to elemental analysis, the powder contained Sn of 96.5% by mass, Ag of 3% by mass and Cu of 0.5% by mass. Incidentally, an amount of the additive to be used (parts by mass) is shown in Table 1, where the metal powder which is the total amount of components of tin, silver and copper before drying is made 100 parts by mass.

### Example 2

In the same manner as in Example 1 except for using 0.80 mg of salicylic acid as an additive, solder powder was obtained. Onto the surface of the solder powder, 0.02 part by mass of salicylic acid had been attached based on 100 parts by mass of the total amount of components of tin, silver and copper contained in the solder powder.

### Example 3

In the same manner as in Example 1 except for using 40 mg of salicylic acid as an additive, solder powder was obtained. Onto the surface of the solder powder, 0.99 part by mass of salicylic acid had been attached based on 100 parts by mass of the total amount of components of tin, silver and copper contained in the solder powder.

### Example 4

In the same manner as in Example 1 except for using 20 mg of ethyl 3,4-dihydroxybenzoate which is an ester of hydroxybenzoic acid as an additive, solder powder was obtained. Onto the surface of the solder powder, 0.46 part by mass of ethyl 3,4-dihydroxybenzoate had been attached based on 100 parts by mass of the total amount of components of tin, silver and copper contained in the solder powder.

### Example 5

In the same manner as in Example 1 except for using 20 mg of ethyl 3,5-dihydroxybenzoate which is an ester of hydroxybenzoic acid as an additive, solder powder was obtained. Onto the surface of the solder powder, 0.48 part by mass of ethyl 3,5-dihydroxybenzoate had been attached based on 100 parts by mass of the total amount of components of tin, silver and copper contained in the solder powder.

### Comparative Example 1

In the same manner as in Example 1 except for not adding an additive, solder powder was obtained.

### Comparative Example 2

In the same manner as in Example 1 except for using 80 mg of salicylic acid as an additive, solder powder was obtained. Onto the surface of the solder powder, 1.9 parts by mass of salicylic acid had been attached based on 100 parts by mass of the total amount of components of tin, silver and copper contained in the solder powder.

### Comparative Example 3

In the same manner as in Example 1 except for using 0.4 mg of salicylic acid as an additive, solder powder was obtained. Onto the surface of the solder powder, 0.00093 part by mass of salicylic acid had been attached based on 100 parts by mass of the total amount of components of tin, silver and copper contained in the solder powder.

### Comparative Example 4

In the same manner as in Example 1 except for using 20 mg of gallic acid as an additive, solder powder was obtained. Onto the surface of the solder powder, 0.45 part by mass of gallic acid had been attached based on 100 parts by mass of the total amount of components of tin, silver and copper contained in the solder powder.

### Comparative Example 5

The solder powder obtained in Comparative example 1 and 20 mg of salicylic acid powder were mixed to obtain solder powder.

### <Comparative Test and Evaluation>

With regard to the solder powder obtained in Examples 1 to 5 and Comparative examples 1 to 5, analysis and measurement of an average particle size and the composition of the powder were carried out by the methods mentioned below, and a ratio of nonaggregated powder and wettability were evaluated. These results are shown in the following Table 1.
(i) Average particle size: Particle size distribution was measured by a particle size distribution measurement device (laser diffraction/scattering type particle size distribution measurement device LA-950 manufactured by HORIBA Ltd.) using a laser diffraction scattering method, and the volume accumulation median diameter (Median diameter, D₅₀) was made to be an average particle size of the solder powder.
(ii) Composition: The contents of the metal elements were measured by using an Inductively Coupled Plasma-Atomic emission spectroscopy (ICP-AES) which uses an ICP emission spectrometer (ICP emission spectrometer: ICPS-7510 manufactured by Shimadzu Corporation). In addition, the contents of the respective additives were measured by High performance liquid chromatography/Ultra-Violet Absorbance Detector (HPLC/UV).
(iii) Nonaggregated powder: The surface of the solder bump after melting was observed by SEM with a magnification of 2,000-fold in the visual field of 50 μm×50 μm, and the quantity of the nonaggregated powder in the one visual field was evaluated by naked eyes.
(iv) Wettability: It was carried out according to the “flux efficacy and dewetting test” described in JISZ3284. With regard to the evaluation, a degree of wetting and spreading was similarly divided into 1 to 4. Incidentally, in Table 1, “1” means the most excellent in wettability in the degree of wetting and spreading, and “4” means the worst wettability.

TABLE 1

| | | | | | | | Average | Number of | |
|---|---|---|---|---|---|---|---|---|---|
| | Additive | | | | | | particle | particles of | Degree of |
| | | Amount used | Sn | Ag | Cu | Additive | size | non-aggregat- | wetting and |
| | Kind | [part by mass] | [% by mass] | | | [part by mass] | [μm] | ed component | spreading |
| Example 1 | Salicylic acid | 0.5 | 96.5 | 3 | 0.5 | 0.49 | 2.3 | <10 | 1 |
| Example 2 | Salicylic acid | 0.02 | 96.5 | 3 | 0.5 | 0.02 | 2.2 | <10 | 1 |
| Example 3 | Salicylic acid | 1.0 | 96.5 | 3 | 0.5 | 0.99 | 2.3 | <10 | 1 |
| Example 4 | 3,4-Di-hydroxy- | 0.5 | 96.5 | 3 | 0.5 | 0.46 | 2.3 | <10 | 1 |
| | benzoic acid | | | | | | | | |
| Example 5 | 3,5-Di-hydroxy- | 0.5 | 96.5 | 3 | 0.5 | 0.48 | 2.3 | <10 | 1 |
| | benzoic acid | | | | | | | | |
| Comparative | — | — | 96.5 | 3 | 0.5 | — | 2.2 | >100 | 3 |
| example 1 | | | | | | | | | |
| Comparative | Salicylic acid | 2.0 | 96.5 | 3 | 0.5 | 1.9 | 2.3 | <100 | 2 |
| example 2 | | | | | | | | | |
| Comparative | Salicylic acid | 0.001 | 96.5 | 3 | 0.5 | 0.00093 | 2.1 | <100 | 2 |
| example 3 | | | | | | | | | |
| Comparative | Gallic acid | 0.5 | 96.5 | 3 | 0.5 | 0.45. | 2.2 | >100 | 4 |
| example 4 | | | | | | | | | |
| Comparative | Mixture of | 0.5 | 96.5 | 3 | 0.5 | 0.50 | 2.2 | <100 | 2 |
| example 5 | salicylic acid | | | | | | | | |
| | powder and | | | | | | | | |
| | solder powder | | | | | | | | |

First, Examples 1 to 5 and Comparative example 1 are compared to each other, as can be clearly seen from Table 1, the solder powder of Comparative example 1 to which no additive is attached is inferior in wettability to those of Examples 1 to 5, and the number of the nonaggregated component is resulted to be 10-fold or more.

Then, when Examples 1 to 5 and Comparative examples 2 to 3 are compared to each other, Examples are excellent in wettability, and the number of the nonaggregated component is within 10, while in Comparative examples, wettability is 2, and the number of the nonaggregated component is resulted to be about 100. From these results, when the additive was attached within the range of 0.02 to 0.99 part by mass based on 100 parts by mass of the total amount of the components comprising tin, silver and copper, it could be confirmed that the effects had been exerted in the degree of wetting and spreading and the number of the nonaggregated component.

Next, in Comparative example 4 using gallic acid as the additive, wettability was inferior to those of Examples 1 to 5, and the number of the nonaggregated component was resulted to be more.

Further, as compared to Examples in which the salicylic acid had been added before drying the solder powder, Comparative example 5 in which the salicylic acid powder had been added after drying was inferior in wettability and the number of the nonaggregated component was resulted to be more. From these results, it can be confirmed that the salicylic acid is attached onto the surface of the solder powder by adding the salicylic acid before drying the solder powder, whereby the antioxidizing effect can be obtained more remarkably.

In Examples 1 to 5, excellent results can be obtained in either of the evaluation than those of Comparative examples 1 to 5.

### INDURASTRIAL APPLICABILITY

The solder powder of the present invention can be utilized as a lead-free solder powder for fine pitch, and the paste for a solder obtained by using the solder powder as a starting material can be suitably used for mounting fine electronic parts.

1. An Sn—Ag—Cu based solder powder which comprises solder powder having an average particle size of 5 μm or less, and a dried material of a solution of hydroxybenzoic acid or an ester thereof having a melting point of 250° C. or lower being attached onto a surface of the solder powder as an additive.

2. The Sn—Ag—Cu-based solder powder according to claim 1, wherein the additive is salicylic acid, ethyl 3,4-dihydroxybenzoate or ethyl 3,5-dihydroxybenzoate.

3. The Sn—Ag—Cu-based solder powder according to claim 1, wherein an attached amount of the additive is 0.01 to 1.0 part by mass based on 100 parts by mass of a total amount of components of tin, silver and copper contained in the solder powder,
a content of the silver is 0.1 to 10% by mass when the total amount of the components of tin, silver and copper is made 100% by mass,
a content of the copper is 0.1 to 2.0% by mass when the total amount of the components of tin, silver and copper is made 100% by mass, and
a remainder is tin.

4. The Sn—Ag—Cu-based solder powder according to claim 1, wherein at least one of bismuth, germanium, nickel and indium is contained with a ratio of 1.0% by mass or less when the total amount of the solder powder is made 100% by mass.

5. A paste for solder obtained by mixing the Sn—Ag—Cu-based solder powder according to claim 1 and a flux for a solder to make a paste.

6. The paste for solder according to claim 5, which is used for mounting electronic parts.
